(19) United States
(12) Patent Application Publication
(10) Pub. No.: US 2016/0204287 A1
(43) Pub. Date: Jul. 14, 2016

(54) METHOD FOR FORMING A PHOTOVOLTAIC CELL

(71) Applicant: COMMISSARIAT À L'ÉNERGIE ATOMIQUE ET AUX ÉNERGIES ALTERNATIVES, Paris (FR)

(72) Inventors: Armand BETTINELLI, Coublevie (FR); Frederic BARBIER, Saint Martin d'Heres (FR)

(73) Assignee: Commissariat a I'energie atomique et aux energies alternatives, Paris (FR)

(21) Appl. No.: 14/916,685

(22) PCT Filed: Sep. 3, 2014
(86) PCT No.: PCT/EP2014/068713

§ 371 Date: Mar. 4, 2016

(30) Foreign Application Priority Data
Sep. 4, 2013 (FR) 13 58456

(51) Int. Cl. H01L 31/0224

(52) U.S. Cl. CPC H01L 31/022425

(57) ABSTRACT

A method for forming a photovoltaic cell including a stack of at least two semi-conducting layers doped according to opposite types of conductivity, the method including a) forming first patterns made of a first conducting material by printing on at least one of faces of the stack; b) forming second patterns made of an insulating material by printing on the at least one of the faces of the stack, such that the insulating material is in contact with at least one part of lateral surfaces of the first patterns and such that thickness of the second patterns is less than that of the first patterns; and c) forming at least one second conducting material by electrolytic deposition on at least the first patterns.

### TECHNICAL FIELD

The present invention relates to a method for forming a photovoltaic cell, and more particularly a method for forming metallisations of a photovoltaic cell.

### STATE OF THE PRIOR ART

The metallisations of a photovoltaic cell are commonly formed by screen printing. The metal normally used to form the metallisations is then silver.

A drawback of methods of printing by screen printing resides in the high resistivity of the metallisations formed.

Methods of printing by screen printing use silver based pastes.

After printing, the depositions of silver based paste are subjected to a heat treatment enabling the deposition to become denser and to obtain a deposition of silver. In the case of homojunction photovoltaic cells for which the heat treatment is carried out at high temperature, for example of the order of 800° C., the resistivity of the depositions of silver after heat treatment is around two times higher than that of solid silver. In the case of heterojunction photovoltaic cells for which the heat treatment is carried out at a temperature of the order of 200° C., the resistivity of the depositions of silver after heat treatment is around four to five times higher than that of solid silver.

To reduce the electrical resistance of the metallisations formed by screen printing on a photovoltaic cell, it is then advisable to increase the quantity of silver deposited on the cell. The result is a high manufacturing cost of a photovoltaic cell of which the metallisations are formed by screen printing.

Screen printing methods enable narrow metallisations to be formed thanks notably to the use of screen printing screens comprising a metal foil of very low thickness (also known as a “stencil”) and high viscosity pastes. Patterns of dimensions less than 50 μm may be obtained. However, the high resistance of the metallisations does not enable high performance photovoltaic cells to be formed.

Furthermore, instead of being formed by screen printing, the metallisations of a photovoltaic cell may be formed by electrolytic deposition (or electrodeposition).

An advantage of electrolytic deposition methods resides in the fact that they make it possible to obtain depositions of silver of resistivity close to that of solid silver. The result is that the quantity of silver to deposit by electrolytic deposition is markedly less than that which would be deposited by screen printing to obtain the same electrical resistance of the metallisations. An electrolytic deposition method makes it possible to deposit around two times less metal for homojunction cells and around four to five times less metal for heterojunction cells, compared to a screen printing method.

Another advantage of electrolytic deposition methods resides in the fact that the metallisations may be made of a metal other than silver, for example copper. Since copper has a resistivity close to that of silver while being less expensive, the result is a reduction in the manufacturing cost of the photovoltaic cells.

FIG. 5A is a top view schematically illustrating an example of formation of metallisations of a photovoltaic cell.

Conducting patterns 105, called “fingers”, form narrow lines, parallel to each other and spaced apart at regular interval. Conducting patterns 111, called “bus-bars”, form lines that are wider than the fingers 105 and which are oriented perpendicularly to the fingers 105. The bus-bars 111 form lines parallel to each other and spaced apart at regular interval. The exposure of a photovoltaic cell to light causes the formation of electrical charges in all the exposed zones of the cell. The fingers 105 are intended to transport these electrical charges from where they have been created to the bus-bars. The bus-bars 111 are intended to receive strips (or wires) of copper, which are either soldered or bonded to the bus-bars and make it possible to transport current from one cell to the other and to connect the cells together. The cells thereby interconnected are encapsulated to form a photovoltaic module.

In the case of heterojunction photovoltaic cells, an optically transparent conducting layer is formed beforehand on the front face of the cells before the formation of the metallisations. To form the metallisations of such cells by electrolytic deposition, it is then advisable to protect the zones of the transparent conducting layer on which it is not wished to form metal. To do so, patterns made of an insulating material are formed beforehand on the transparent conducting layer.

The patterns of insulating material could be formed by photolithography. However, such methods are costly and thus difficult to use during a method of manufacturing photovoltaic cells.

A solution consists in using a laser to form the patterns of insulating material. To do so, an insulating layer is formed entirely covering the front face of the photovoltaic cell and a laser is then used to eliminate portions of the insulating layer in order to form the desired patterns. However, in the case where an optically transparent insulating layer is selected in order to be able to conserve it at the end of the method of manufacturing the photovoltaic cell, it is difficult to form the patterns without damaging the underlying transparent conducting layer, because the layer to eliminate is optically transparent just like the stop layer. In the case of a non-transparent insulating layer, although the laser beam is in part absorbed by the insulating layer, it is also difficult to eliminate entirely the insulating material in the desired zones without damaging the underlying transparent conducting layer.

Moreover, a drawback of electrolytic deposition methods resides in the low adherence of the metallisations formed.

In the case of homojunction cells, a solution for improving the adherence of the metallisations on the faces of the stack of semi-conducting layers constituting the photovoltaic cell consists in forming an adherence sub-layer, for example made of nickel silicide, before forming the metallisations.

However, there exists a difficult compromise to satisfy to find the conditions of formation of a metal silicide having high adherence while avoiding short-circuits.

In the case of heterojunction cells, the adherence of the metallisations formed by electrolytic deposition on a transparent conducting layer is even lower than in the case where they are formed on a semi-conducting layer. Moreover, it is difficult to form an adherence sub-layer made of a metal silicide because metal silicides are formed at temperatures markedly higher than the temperatures withstood by heterojunction cells.

The problem is thus posed of forming metallisations of a photovoltaic cell having low resistivity and high adherence.

The problem is also posed of forming metallisations of a photovoltaic cell by a method having a reduced cost.

### DESCRIPTION OF THE INVENTION

The present invention aims notably to resolve these problems.

On account of the difficulties described above to form patterns of insulating material on a transparent conducting layer in the case of heterojunction cells, the inventors have also sought to form patterns of insulating material by a method other than photolithography and laser. They have then sought to use a printing technique such as screen printing to form patterns of insulating material and have identified certain problems.

In fact, the low viscosities required for depositions of large surface lead to losses of definition of the patterns printed in insulating material.

FIG. 6 is a top view schematically illustrating patterns 109 of a screen printing screen being able to be used to form patterns of insulating material, for example on a transparent conducting layer.

FIG. 7 is a top view schematically illustrating insulating patterns 107 printed by screen printing using the screen printing screen of FIG. 6.

As may be seen in FIG. 7, spreadings of irregular extent are produced on the edges of the patterns 107 leading to considerable fluctuations in the dimensions of the openings. The fluctuations in the dimensions of the openings increase as printing progresses. It is possible to avoid the dimensions of the openings reducing as printing progresses by carrying out regular cleanings of the surface of the screen printing screen but this does not eliminate the irregularities of the edges of the patterns. Thus, even with regular cleaning of the screen printing screen, it is difficult to form in a reproducible manner openings of dimensions of the order of 50 μm.

An object of the present invention further aims to resolve these problems.

The present invention relates to a method for forming a photovoltaic cell comprising a stack of at least two semi-conducting layers doped according to opposite types of conductivity, including the following steps:

a) forming first patterns made of a first conducting material by printing on at least one of the faces of the stack;

b) forming the second patterns made of an insulating material, by printing on said at least one of the faces of the stack, such that the insulating material is in contact with at least one part of the lateral surfaces of the first patterns and such that the thickness of the second patterns is less than that of the first patterns; and

c) forming at least one second conducting material by electrolytic deposition on at least the first patterns.

An advantage of a method for forming metallisations of a photovoltaic cell of the type of that described above is linked to the fact that it uses the high adherence of the first conducting patterns formed beforehand by printing during step a) and the low resistivity of the major part of the metallisations formed by electrolytic deposition during step c).

The result is a low resistivity of the metallisations formed.

Moreover, since only a part of the metallisations is formed by printing, the result is a reduced manufacturing cost of the photovoltaic cells.

Another advantage of a method of the type of that described above is linked to the fact that the thickness of the second insulating patterns is chosen so as to be less than that of the first conducting patterns. This makes it possible to form the second conducting material by electrolytic deposition not only on the upper surface of the first conducting patterns but also on the portions of the lateral surfaces of the first conducting patterns which are not in contact with the second insulating patterns. The result is an increase in the adherence of the second conducting material on the first conducting patterns, compared to the case where the second conducting material would form only on the upper surface of the first conducting patterns.

Another advantage of a method of the type of that described above resides in the fact that the second insulating patterns formed during step b), before step c) of electrolytic deposition, may be conserved after this step, up to the end of the method of manufacturing the photovoltaic cell and even after the photovoltaic cells are formed into modules.

According to an embodiment of the present invention, the method further includes, after step c) of electrolytic deposition, a step d) of elimination of the second insulating patterns.

According to an embodiment of the present invention, during step a), the first conducting patterns are formed by screen printing or by a technique of direct contactless printing, for example a distribution technique known as “dispensing”.

According to an embodiment of the present invention, during step b), the second insulating patterns are formed by screen printing.

According to an alternative, during step b), the second insulating patterns may be formed by ink jet printing.

According to an embodiment of the present invention, the ratio of the thickness of the first conducting patterns to the thickness of the second insulating patterns is comprised between 1.2 and 2.5.

According to an embodiment of the present invention, during step a), the aspect ratio of the first conducting patterns, corresponding to the ratio of the height to the width of the patterns, is greater than 0.5.

The first conducting material may be selected from the group including silver, copper and aluminium or may be a material including a metallic element selected from the group including silver, copper and aluminium.

The insulating material may be an insulating organic resin.

The second conducting material may be silver or copper.

An advantage of a method of the type of that described above resides in the fact that the metallisations may be made of a metal other than silver, for example copper. The result is a reduction in the manufacturing cost of the photovoltaic cells.

According to an embodiment of the present invention, during step c), a stack of several layers of conducting materials is formed by electrolytic deposition.

The stack of several layers of conducting materials may comprise a barrier layer covered with a layer of the second conducting material itself covered with a surface layer.

The barrier layer may be made of nickel. The second conducting material may be silver or copper. The surface layer may be made of silver or tin.

According to an embodiment of the present invention, before step a) of formation of the first conducting patterns, said at least one of the faces of the stack is covered with a transparent conducting layer.

The transparent conducting layer may be based on a conducting transparent oxide such as ITO (“indium tin oxide”, oxide of indium and tin), or IO (indium oxide), or IWO (oxide of indium and tungsten) or ZnO (zinc oxide).

An advantage of a method for forming metallisations of a photovoltaic cell of the type of that described above resides in the fact that the metallisations formed have high adherence on the faces of the photovoltaic cell, notably in the case where they are covered with a transparent conducting layer. The result is that the interconnections formed later between these metallisations and conducting strips are of good quality. This makes it possible to manufacture photovoltaic cells having enhanced performances. Moreover, it is not necessary to form an adherence sub-layer on the faces of the photovoltaic cell before forming the metallisations.

According to an embodiment of the present invention, before step a), the transparent conducting layer is covered with a conducting adherence layer.

According to an embodiment of the present invention, during step a), the first patterns formed by printing include conducting lines parallel to each other, potentially spaced apart at regular interval and/or advantageously discontinuous.

According to an embodiment of the present invention, during step b) of formation of the second patterns, bus zones are defined, potentially oriented perpendicularly to the first patterns, corresponding to portions of said at least one of the faces of the stack not covered by the second patterns.

According to an embodiment of the present invention, during step a), conducting pads are moreover formed by printing on said at least one of the faces of the stack, the conducting pads being arranged in the bus zones.

The bus zones may be discontinuous. In this case, during step a), at least one conducting pad is formed in each portion of the bus zones.

According to an embodiment of the present invention, the zones for connecting the first patterns with the bus zones are wider than the remainder of the first patterns.

### BRIEF DESCRIPTION OF THE DRAWINGS

Other characteristics and advantages of the invention will become clearer on reading the following description and with reference to the appended drawings, given uniquely by way of indication and in no way limiting.

FIGS. 1A to 1D are sectional views schematically illustrating the successive steps of a method for forming metallisations of a photovoltaic cell according to the invention.

FIG. 2 is a top view corresponding to FIG. 1B.

FIGS. 3A and 3B are top views illustrating variants of a method for forming metallisations of a photovoltaic cell according to the invention, respectively in the case of continuous bus zones and in the case of discontinuous bus zones.

FIG. 4 is a top view illustrating another variant of a method for forming metallisations of a photovoltaic cell according to the invention.

FIGS. 5A and 5B are top views schematically illustrating examples of formation of metallisations of a photovoltaic cell.

FIG. 6 is a top view schematically illustrating patterns of a screen printing screen.

FIG. 7 is a top view schematically illustrating the insulating patterns printed by screen printing using the screen printing screen of FIG. 6.

Identical, similar or equivalent parts of the different figures bear the same numerical references so as to made it easier to go from one figure to the next.

The different parts represented in the figures are not necessarily according to a uniform scale in order to make the figures more legible.

### DETAILED DESCRIPTION OF PARTICULAR EMBODIMENTS

The inventors propose, in order to form the metallisations of a photovoltaic cell, forming beforehand conducting patterns by printing, for example by screen printing, then forming the major part of the metallisations by electrolytic deposition.

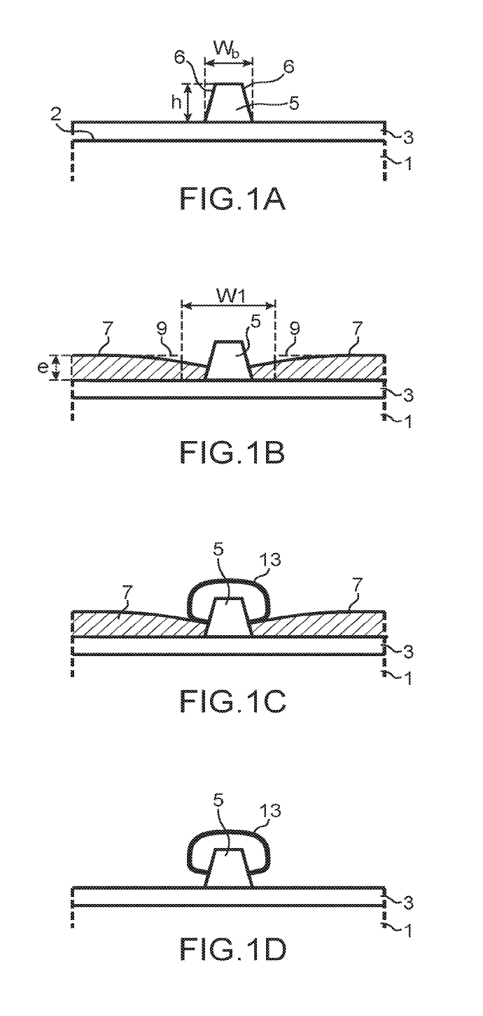

FIGS. 1A to 1D are sectional views schematically illustrating the successive steps of a method for forming metallisations of a photovoltaic cell. For reasons of simplification, only one of the two faces of the photovoltaic cell is represented in these figures. Obviously, the method described hereafter applies to the formation of metallisations on one and/or the other of the faces of the photovoltaic cell.

FIG. 1A represents the upper part 1 of a stack of semi-conducting layers of a photovoltaic cell. The stack includes at least two semi-conducting layers doped according to opposite types of conductivities forming a PN junction. The stack includes two main faces, only one of the two faces, the face 2, being represented in FIG. 1A. The face 2 is for example the front face of the photovoltaic cell, i.e. the face which is intended to be exposed to light radiation.

The face 2 is for example covered with a transparent conducting layer 3, for example based on a conducting transparent oxide such as ITO (“indium tin oxide”, oxide of indium and tin), or IO (indium oxide), or IWO (oxide of indium and tungsten) or ZnO (zinc oxide). Potentially, the transparent conducting layer 3 is covered with a conducting adherence layer (not represented), for example a layer of titanium or silver or copper formed by physical deposition in a vapour phase (PVD, “Physical Vapour Deposition”). But, it is not necessary to form an adherence sub-layer on the faces of the photovoltaic cell before forming the metallisations.

Patterns 5 made of a conducting material are formed on the transparent conducting layer 3 by a printing method, for example by screen printing. The patterns 5 are for example made of silver or copper or aluminium, or made of a material including a metallic element such as silver, copper or aluminium. When the metallisations are made of a metal other than silver, for example copper, the result is a reduction in the manufacturing cost of the photovoltaic cells.

The conducting patterns 5 form for example lines parallel to each other, spaced apart at regular interval and advantageously discontinuous. In this case, the patterns 5 are called “fingers”. As is represented in FIG. 1A, the transversal section of the patterns 5, in a plane perpendicular to the direction of the lines, is for example of trapezoidal shape. The section of the patterns 5 may also be of any shape.

Advantageously, the aspect ratio of the patterns 5, corresponding to the ratio of the height h to the width W of the patterns, is high. The aspect ratio of the patterns 5 is preferably greater than 0.5. In the case of patterns of trapezoidal section, the width W of the patterns is for example defined by the width of the base W_{b}. The patterns of trapezoidal section having a high aspect ratio have sides or lateral surfaces 6 of high slope.

As an example of dimensions, for patterns 5 of trapezoidal section, the width of the base W_{b} may be of the order of 32 μm, the width at mid-height may be of the order of 20 μm and the height h may be of the order of 17 μm, which corresponds to an aspect ratio of the order of 0.53.

According to another example of dimensions, for patterns 5 of trapezoidal section, the width of the base W_{b} may be of the order of 40 μm, the width at mid-height may be of the order of 25 μm and the height h may be of the order of 25 μm, which corresponds to an aspect ratio of the order of 0.62.

In the case where the patterns 5 are formed by screen printing, screen printing screens will be used comprising a metal foil of very low thickness (also known as a “stencil”) making it possible to form patterns of high form factor. Preferably stencils will be used making it possible to obtain patterns 5 of trapezoidal section.

As an example, using stencils of thickness of the order of 30 μm, including openings of around 27 μm width on the side of the lower face in contact with the photovoltaic cell and of around 17 μm width on the side of the upper face, it is possible to obtain patterns 5 of trapezoidal section of width at mid-height of around 20 μm. Even thinner stencils, for example of thickness of the order of 20 μm, could be used to reduce the consumption of paste.

Once the patterns 5 are printed, a heat treatment is carried out in conditions making it possible to obtain the adherence and the resistivity desired for the conducting patterns 5.

Advantageously, pastes known as “low temperature” will be used, suited to low temperature heat treatment. For example pastes constituted of an organic matrix, for example an epoxy type resin, including metal powders will be used. These “low temperature” pastes make it possible to form conducting patterns 5 having high adherence on the transparent conducting layer 3. Moreover, the adherence of the patterns 5 on the transparent conducting layer 3 will be conserved during the later step of electrolytic deposition illustrated in FIG. 1C.

As an example, “low temperature” pastes suited to heat treatment at a temperature of the order of 200° C. will be used. In the case where the face 2 is covered with a transparent conducting layer 3 itself covered with an oxidisable adherence layer, for example made of copper, pastes suited to heat treatment at a temperature of the order of 150° C. will preferably be chosen.

Instead of forming the conducting patterns 5 by screen printing, other printing methods could be used. Any other printing method making it possible to form conducting patterns with a high form factor and having high adherence could be used to form the conducting patterns 5. Direct contactless printing methods, designated as “dispensing” methods, could for example be used.

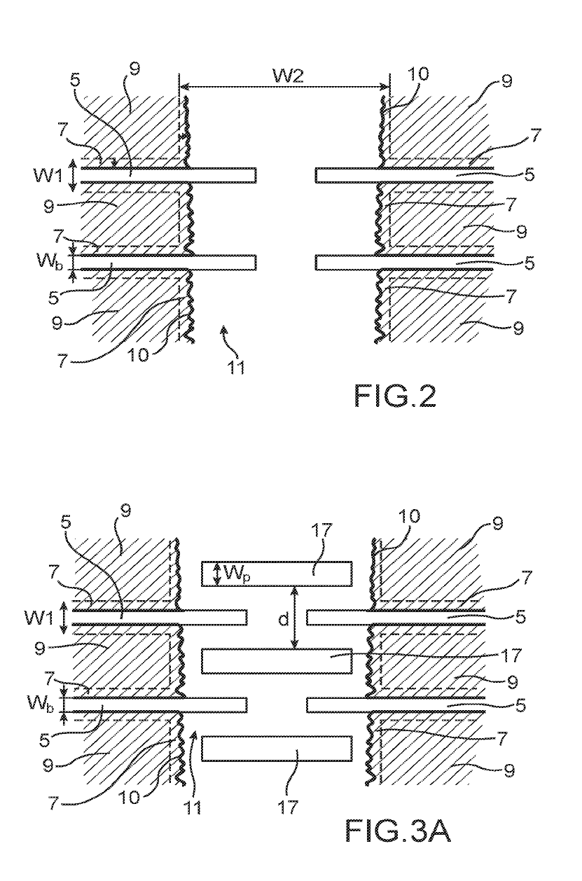

FIG. 1B illustrates the formation of patterns 7 made of an insulating material on the transparent conducting layer 3 by a printing method, for example by screen printing. FIG. 2 is a top view corresponding to FIG. 1B.

The patterns 7 may be made of a transparent insulating material.

In this case, the insulating patterns 7 could remain on the photovoltaic cell at the end of the method for forming metallisations. The transparent insulating material may be an inorganic material, for example SiO₂ or SiN, or an organic material. An organic material will preferably be chosen, for example a transparent polymer, which is stable and compatible with the method of encapsulation used for the formation of the photovoltaic cells into modules. The insulating material 7 is for example a resin based on silicone or any other polymer having a viscosity suited to printing by screen printing and good stability with respect to ultraviolet radiation.

According to an alternative, the patterns 7 may be formed of a non-transparent insulating material. In this case, the insulating patterns 7 will be eliminated after the step of electrolytic deposition described hereafter in relation with FIG. 1C. The non-transparent insulating material may be an inorganic material or an organic material. An organic material, for example a resin, will preferably be chosen.

In the case where the insulating patterns 7 are formed by screen printing, a screen printing screen will be used having openings of width W1 greater than the width W_{b} of the base of the conducting patterns 5. The patterns of insulating material which would be obtained without spreading and if they corresponded to the patterns defined on the screen printing screen are represented by zones 9 delimited by dotted lines in FIGS. 1B and 1n FIG. 2.

Those skilled in the art will know how to choose an insulating material of suitable viscosity such that, after spreading the insulating material, the insulating patterns 7 are in contact with the lateral surfaces 6 of the conducting patterns 5, as is represented in FIGS. 1B and 1n FIG. 2.

The conducting patterns 5 formed during the preceding step have preferably a high aspect ratio, which makes it possible to obtain conducting patterns 5 having lateral surfaces 6 of high slope. The result is that, during the spreading of the insulating material 7 (represented by arrows in FIG. 2), said material stops in a clear manner on the lateral surfaces of the conducting patterns 5.

Printing equipment provided with a viewing system compatible with precise alignments will be used, which is the case of current equipment which enables alignments to more or less some 15 μm, or better.

As an example, in the case of a resin of viscosity leading to natural spreading of around 70 μm with respect to a pattern edge, it is possible to use a screen printing screen having openings of width W1 of the order of 120 μm. This makes it possible to take into account alignment defects and spreading irregularities.

As may be seen in FIG. 2, the edges 10 of the insulating patterns 7 which are not in contact with the conducting patterns 5 have irregularities.

Nevertheless, these irregularities do not matter given the width W2 of the defined zones 11, called bus zones. The bus zones 11 correspond to the locations where the bus-bars will be formed. The contours 10 of the bus zones 11 could potentially be defined in a more precise manner by forming, during the step illustrated in FIG. 1A, patterns of conducting material on which the edges 10 of the insulating patterns 7 come to stop. In the example illustrated in FIG. 2, the conducting patterns 5 are discontinuous and the discontinuities of the conducting patterns 5 are located in the bus zones 11.

The thickness e of the insulating patterns 7 is chosen so as to be less than the thickness, or height, h of the conducting patterns 5. The ratio h/e between the thickness of the conducting patterns 5 and that of the insulating patterns 7 is preferably comprised between 1.2 and 2.5.

As an example, the thickness of the conducting patterns 5 may be of the order of 17 μm and the thickness of the insulating patterns 7 may be of the order of 8 urn, which corresponds to a ratio h/e of the order of 2.1.

According to another example, the thickness of the conducting patterns 5 may be of the order of 25 μm and the thickness of the insulating patterns 7 may be of the order of 15 μm, which corresponds to a ratio h/e of the order of 1.7.

Once the insulating patterns 7 are printed, a heat treatment is carried out. The heat treatment conditions will be chosen so as to obtain good adherence of the insulating patterns 7 on the photovoltaic cell. In fact, during the step illustrated in FIG. 1C, the photovoltaic cell will be immersed in one or more electrolytic deposition baths. Since the insulating patterns 7 are intended to protect the zones on which it is not wished to form conducting material, they must remain properly in place when the cell is immersed in the electrolytic deposition baths. Potentially, the heat treatment conditions will be also chosen such that the insulating patterns 7 can be eliminated after the electrolytic deposition.

For example a heat treatment could be carried out at a temperature comprised between around 80° C. and around 120° C. In the case where the insulating material is conserved after the step of electrolytic deposition, the heat treatment could be carried out at higher temperatures.

Instead of forming the insulating patterns 7 by screen printing, other printing methods could be used, for example ink jet printing methods.

Nevertheless, ink jet printing methods have the drawback of lower throughput compared to screen printing.

FIG. 1C illustrates the formation of at least one conducting material 13 by electrolytic deposition. The conducting material 13 is for example silver or copper.

The photovoltaic cell is immersed in one or more electrolytic deposition baths.

The conducting material 13 forms on the portions of the conducting patterns 5 which are not in contact with the insulating patterns 7. The conducting material 13 also forms on the portions of the transparent conducting layer 3 which are not covered by the insulating patterns 7, and in particular potentially on the bus zones 11 in order to form the bus-bars at the same time as the fingers. More generally, the insulating patterns 7 serve as mask during the electrolytic deposition step, such that the conducting material 13 is deposited on the portions of transparent conducting layer 3 left free by the mask and corresponding to the openings in said mask.

The adherence of the conducting material 13 formed by electrolytic deposition on the conducting patterns 5 formed by printing is high thanks to metal-metal bonds. Moreover, since the metallisations are formed by electrolytic deposition, they will have low resistivity.

The thickness e of the insulating patterns 7 formed during the step illustrated in FIG. 1B has been chosen so as to be less than the thickness h of the conducting patterns 5. The conducting material 13 then forms not only on the upper surface of the conducting patterns 5 but also on the portions of the lateral surfaces of the conducting patterns 5 which are not in contact with the insulating patterns 7. This makes it possible to increase the adherence of the conducting material 13 on the conducting patterns 5, compared to the case where the conducting material 13 would form only on the upper surface of the conducting patterns 5.

A stack of several layers of conducting materials may be formed by electrolytic deposition. The stack of conducting layers may comprise a barrier layer, for example made of nickel, covered with a conducting layer 13 made of silver or copper, itself covered with a thin surface conducting layer, for example made of silver or tin. The thin surface conducting layer is chosen so as to obtain interconnections of good quality with the conducting strips formed later for the formation of the photovoltaic cells into modules.

The thickness of the conducting layer 13 is greater than those of the barrier layer and the surface layer.

FIG. 1D illustrates the potential elimination of the insulating material 7. This optional step is for example carried out in the case where the insulating material 7 is not transparent or in the case where it is not compatible with later steps of the formation of the photovoltaic cells into modules.

According to a variant, the insulating patterns 7 are conserved after the electrolytic deposition step illustrated in FIG. 1C. The insulating patterns 7 may be conserved up to the end of the method of manufacturing the photovoltaic cell and even after the formation of the photovoltaic cells into modules.

Although the method for forming metallisations of a photovoltaic cell illustrated in FIGS. 1A-1D has been described in the case where a transparent conducting layer 3 covers the face 2 of the cell, the method applies to the formation of metallisations directly on the face 2 of the cell (potentially covered with a conducting adherence layer).

An advantage of a method for forming metallisations of a photovoltaic cell of the type of that described in relation with FIGS. 1A-1D is linked to the fact that it uses the high adherence of the conducting patterns 5 formed beforehand by printing and the low resistivity of the major part of the metallisations formed by electrolytic deposition.

Another advantage of a method for forming metallisations of a photovoltaic cell of the type of that described in relation with FIGS. 1A-1D resides in the fact that the metallisations formed have high adherence on the faces of the photovoltaic cell, notably in the case where they are covered with a transparent conducting layer. The result is that the interconnections formed later between these metallisations and the conducting strips are of good quality.

This makes it possible to manufacture photovoltaic cells having enhanced performances.

Another advantage of a method of the type of that described in relation with FIGS. 1A-1D is linked to the fact that only a part of the metallisations is formed by screen printing. The bus-bars as well as a part of the fingers are formed by electrolytic deposition. The result is a reduced manufacturing cost of the photovoltaic cells.

During the interconnection of the strips enabling the formation of the photovoltaic cells into modules, and during stresses undergone by the photovoltaic module during its use, for example during differential expansions due to temperature variations, it is the bus-bars, on which are formed the interconnections with the strips of copper, which are the most strained.

In order to reinforce the adherence of the metallisations in the bus zones, it is possible, during the step of formation of the conducting patterns 5 by printing, to also form conducting patterns in these bus zones.

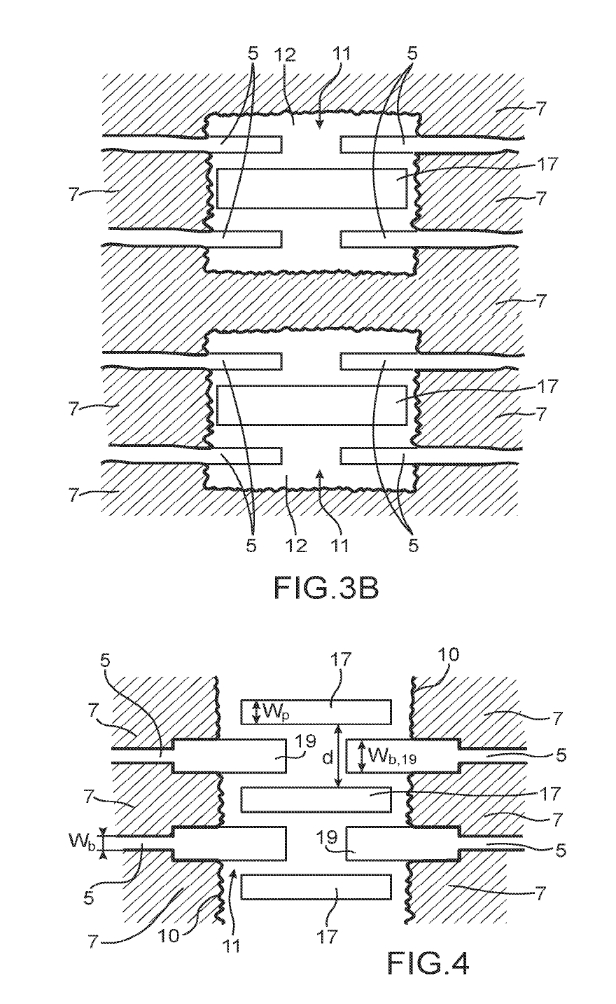

FIG. 3A is a top view illustrating such a variant of the method for forming metallisations of a photovoltaic cell described in relation with FIGS. 1A-1D and 2. FIG. 3A, corresponding to FIG. 2, represents the structure obtained after the step of formation of the insulating patterns 7 illustrated in FIG. 1B.

During a step of formation by printing of the conducting patterns 5 illustrated in FIG. 1A, conducting pads 17 are also formed in the bus zones 11.

The dimensions and the number of conducting pads 17 will be chosen so as to obtain sufficient adherence of the conducting material 13 formed by electrolytic deposition during the step illustrated in FIG. 1C, while minimising the quantity of conducting material used. The dimensions and the number of conducting pads 17 will also be chosen as a function of the nature of the paste used for the printing and as a function of the dimensions of the strips to interconnect.

As an example, in the bus zones 11, conducting pads 17 will be able to be formed in the form of lines parallel to each other and spaced apart at regular interval. The lines have for example a width Wₚ of the order of 200 μm and are for example spaced apart by a distance d of the order of 1 mm.

The conducting pads 17 may be of any shape. They may for example be formed in an “S” shape, this shape of patterns being well controlled by methods of screen printing by stencil.

Once the conducting patterns 5 and the conducting pads 17 are printed, a heat treatment is carried out in conditions making it possible to obtain the desired resistivity and adherence for the patterns 5 and the pads 17.

In the case of a conducting paste made of silver, the heat treatment is for example carried out for around 10 min at a temperature of around 200° C.

Since the conducting pads 17 are formed by printing, for example by screen printing, they have high adherence on the transparent conducting layer 3. They thus make it possible to improve the adherence of the conducting material 13 formed later by electrolytic deposition. The result is an improvement in the reliability of the interconnections.

FIG. 4 is a top view illustrating another variant of the method described in relation with FIGS. 1A-1D. FIG. 4, corresponding to FIG. 2, represents the structure obtained after the step of formation of the insulating patterns 7 illustrated in FIG. 1B.

During the step illustrated in FIG. 1A of formation of the conducting patterns 5 by printing, and potentially conducting pads 17 in the bus zones, instead of forming patterns 5 of constant width W_{b}, patterns 5 could be formed with particular geometries in the zones 19 for connecting between fingers 5 and bus zones 11. For example, conducting patterns 5 could be formed of which the width W_{b,19} in the zones 19 is greater than the width W_{b} of the remainder of the patterns 5. This makes it possible to reinforce mechanically the fingers in the vicinity of the interconnection zones with the strips while improving the conduction of electrical charges.

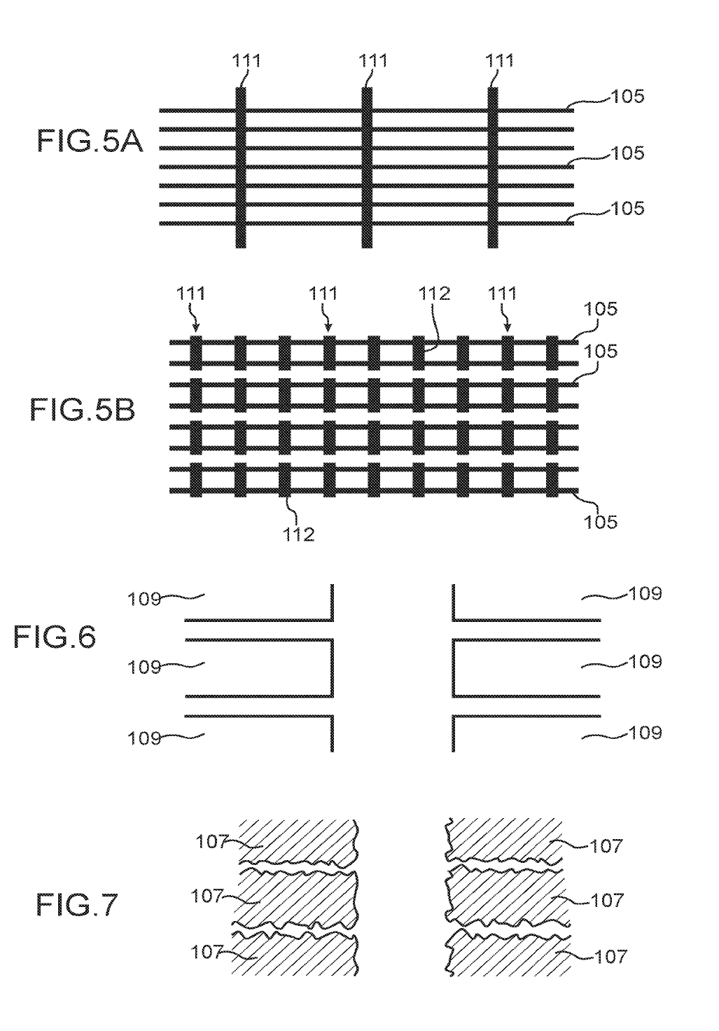

More generally, this reinforcement of the adherence of metallisations in the bus zones, by formation of conducting patterns by printing in said bus zones, may apply to any geometries of metallisations of cells, and not uniquely to the normal “H” shaped patterns described by way of example in relation with FIG. 5A (continuous bus-bars 111 perpendicular to the network of fingers 105) and dedicated to the usual interconnection of cells from two to five strips of copper. The metallisations may for example have bus-bars of irregular widths or discontinuous bus-bars. The conducting pads 17 may be of any shape and are formed in the continuous or discontinuous bus zones corresponding to the future bus-bars.

FIG. 5B is a top view schematically illustrating another example of formation of metallisations of a photovoltaic cell than that of FIG. 5A. The bus-bars 111, perpendicular to the fingers 105, are discontinuous. Each bus-bar 111 is constituted of several portions 112, each portion 112 being connected to one or more fingers 105. In the example illustrated in FIG. 5B, each portion 112 is connected to two fingers 105. The portions 112 of each bus-bar 111 are not necessarily electrically connected together during the formation of the metallisations. They will be after the formation of the interconnections with strips of copper.

FIG. 3B is a top view corresponding to FIG. 3A in the case where the bus zones 11 are discontinuous. During the step of formation of the conducting patterns 5 by printing, at least one conducting pad 17 is formed in each portion 12 of the discontinuous bus zones 11.

1-16. (canceled)

17. A method for forming a photovoltaic cell including a stack of at least two semi-conducting layers doped according to opposite types of conductivity, the method comprising:
a) forming first patterns made of a first conducting material by printing on at least one of faces of the stack;
b) forming second patterns made of an insulating material, by printing on the at least one of the faces of the stack, such that the insulating material is in contact with at least one part of lateral surfaces of the first patterns and such that thickness of the second patterns is less than that of the first patterns; and
c) forming at least one second conducting material by electrolytic deposition on at least the first patterns.

18. A method according to claim 17, further comprising, after c), d) elimination of the second patterns.

19. A method according to claim 17, wherein, during a), the first patterns are formed by screen printing or by direct contactless printing.

20. A method according to claim 17, wherein, during b), the second patterns are formed by screen printing or by ink jet printing.

21. A method according to claim 17, wherein the ratio of the thickness of the first patterns to the thickness of the second patterns is between 1.2 and 2.5.

22. A method according to claim 17, wherein, during a), the aspect ratio of the first patterns is greater than 0.5.

23. A method according to claim 17, wherein the first conducting material is selected from the group of silver, copper and aluminium or is a material including a metallic element selected from the group of silver, copper and aluminium.

24. A method according to claim 17, wherein the insulating material is an insulating organic resin.

25. A method according to claim 17, wherein the second conducting material is selected from the group of silver and copper.

26. A method according to claim 17, wherein a barrier layer is formed by electrolytic deposition prior to the second conducting material and a surface layer made of a conducting material is formed by electrolytic deposition after the second conducting material, to form a stack of plural layers of conducting materials.

27. A method according to claim 17, wherein, before a), the at least one of the faces of the stack is covered with a transparent conducting layer.

28. A method according to claim 17, wherein, during a), the first patterns formed by printing include conducting lines parallel to each other.

29. A method according to claim 28, wherein, during b), bus zones are defined corresponding to portions of the at least one of the faces of the stack not covered by the second patterns.

30. A method according to claim 29, wherein, during a), conducting pads are further formed by printing on the at least one of the faces of the stack, the conducting pads being arranged in the bus zones.

31. A method according to claim 30, wherein the bus zones are discontinuous, and, during a), at least one conducting pad is formed in each portion of the bus zones.

32. A method according to claim 29, wherein the zones for connecting the first patterns with the bus zones are wider than a remainder of the first patterns.
